(19) United States
(12) Patent Application Publication
(10) Pub. No.: US 2025/0038067 A1
(43) Pub. Date: Jan. 30, 2025

(54) SEMICONDUCTOR DEVICE

(71) Applicants: nD-HI Technologies Lab, Inc., Taipei City (TW); ETRON TECHNOLOGY, INC., Hsinchu (TW)

(72) Inventors: Ho-Ming Tong, Taipei City (TW); Chih-Hsun HSIEH, Taipei City (TW); Chao-Chun LU, Hsinchu (TW)

(73) Assignees: nD-HI Technologies Lab, Inc., Taipei City (TW); ETRON TECHNOLOGY, INC., Hsinchu (TW)

(21) Appl. No.: 18/785,296

(22) Filed: Jul. 26, 2024

Related U.S. Application Data
(60) Provisional application No. 63/516,356, filed on Jul. 28, 2023.
(60) Provisional application No. 63/519,456, filed on Aug. 14, 2023.
(60) Provisional application No. 63/519,484, filed on Aug. 14, 2023.
(60) Provisional application No. 63/582,106, filed on Sep. 12, 2023.

(51) Int. Cl. H01L 23/373; H01L 23/467; H01L 23/528; H10B 10/00

(52) U.S. Cl. CPC H01L 23/3738; H01L 23/467; H01L 23/5283; H01L 23/5286; H10B 10/12

(57) ABSTRACT

A semiconductor device includes a substrate, a memory component and a heat dissipation component. The memory component is disposed on the substrate. The heat dissipation component is disposed on the substrate. The heat dissipation component has a thermal conductivity greater than that of silicon.

This application claims the benefit of U.S. provisional application Ser. No. 63/516,356, filed Jul. 28, 2023, the disclosures of which are incorporated by reference herein in its entirety, claims the benefit of U.S. provisional application Ser. No. 63/519,456, filed Aug. 14, 2023, the disclosures of which are incorporated by reference herein in its entirety, claims the benefit of U.S. provisional application Ser. No. 63/519,484, filed Aug. 14, 2023, the disclosures of which are incorporated by reference herein in its entirety, and claims the benefit of U.S. provisional application Ser. No. 63/582,106, filed Sep. 12, 2023, the disclosures of which are incorporated by reference herein in its entirety.

### TECHNICAL FIELD

The disclosure relates in general to a semiconductor device.

### BACKGROUND

A front-side (wafer front-end-of-line, FEOL/back-end-of-line, BEOL side) of an ultra-thin memory device, e.g., cache memory, SRAM (static random-access memory), NAND or DRAM, and a plurality of dummy silicon pieces are bonded to the backside of an ultra-thin, high-power processor (e.g., at 100 W or higher/chip) with a front-side power delivery network using copper hybrid bonding involving oxide-to-oxide direct bonding. The memory mounted processor is bonded to a substrate. The substrate is mounted on a socket for electrical connections. However, heat generated by relatively high-power processors (e.g., 100 W) may cause blistering/delamination/cracking failures in the processor as heat generated by processors are hard to dissipate through the oxide layer bonded to processor by the memory (e.g., cache memory).

### SUMMARY

Example embodiment 1: a semiconductor device is provided. The semiconductor device includes a substrate; a memory component (or a logic component or a combination of memory and logic components) disposed on the substrate; and a heat dissipation component disposed on the substrate. The heat dissipation component has a thermal conductivity greater than that of silicon.

Example embodiment 2 based on Example embodiment 1: the heat dissipation component is made of a material including diamond, aluminum nitride, boron nitride, boron arsenide, silicon carbide, metal or a combination thereof.

Example embodiment 3 based on Example embodiment 1: the memory component and the heat dissipation component are disposed side by side.

Example embodiment 4 based on Example embodiment 1: the semiconductor device further includes a plurality of the heat dissipation components. The memory component is disposed between the heat dissipation components.

Example embodiment 5 based on Example embodiment 1: the semiconductor device further includes a plurality of the memory components. The heat dissipation component is disposed between the memory components.

Example embodiment 6 based on Example embodiment 1: the semiconductor device further includes a molding compound disposed between the memory component and the heat dissipation component.

Example embodiment 7 based on Example embodiment 1: the semiconductor device further includes a plurality of the heat dissipation components; and a molding compound disposed between the heat dissipation components.

Example embodiment 8 based on Example embodiment 1: the semiconductor device further includes a plurality of the memory components; and a molding compound disposed between the memory components.

Example embodiment 9 based on Example embodiment 1: the semiconductor device further includes a heat spreader including a vapor chamber and covering the memory component and the heat dissipation component and having an upper surface; a cooling component disposed on the upper surface of the heat spreader and having a fluid channel; and a fan and/or a heat exchanger thermally coupled to the cooling component.

Example embodiment 10 based on Example embodiment 9: the semiconductor device further includes a molding compound on a lateral surface of the heat dissipation component and having a lateral surface. The lateral surface of the molding compound and a lateral surface of the substrate are flushed with each other.

Example embodiment 11 based on Example embodiment 1: the substrate includes a power rail layer; a power supply layer connected with the power rail layer; and an interposer disposed adjacent to and thermally coupled to the power supply layer, wherein the interposer is made of diamond, aluminum nitride, boron nitride, boron arsenide, silicon carbide, metal or a combination thereof.

Example embodiment 12 based on Example embodiment 1: the substrate includes a BEOL structure; and a thermal Isolation structure disposed on and/or within the BEOL structure.

Example embodiment 13 based on Example embodiment 1: the substrate includes a BEOL structure; and a heat spreading structure disposed on and/or within the BEOL structure.

Example embodiment 14 based on Example embodiment 1: the substrate includes a processor core; a cache memory disposed adjacent to the processor core; a thermal metamaterial structure disposed between the processor core and the L3 cache and between the L3 cache and the memory component to minimize thermal cross-talks, respectively, between the processor core and the L3 cache and between the L3 cache and the memory component.

Example embodiment 15 based on Example embodiment 14: the thermal metamaterial structure is a thermal-guiding ring including a first layer, a second layer and a third layer. The first layer has a first thermal conductivity. The second layer has a second thermal conductivity and surrounds the first layer. The third layer has a third thermal conductivity and surrounds the second layer. The second thermal conductivity is greater than the first thermal conductivity, and the first thermal conductivity is greater than the third thermal conductivity.

Example embodiment 16 based on Example embodiment 15: the first layer is formed of silicon, the second layer is formed of graphene, and the third layer is formed of silicon dioxide.

Example embodiment 17 based on Example embodiment 16: the semiconductor device is mounted on a HTC and LCTE substrate.

Example embodiment 18 based on Example embodiment 1: the substrate includes a FEOL structure; and a thermal Isolation structure disposed on and/or within the FEOL structure.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a schematic diagram of a semiconductor device 10 according to an embodiment of the present disclosure;

FIG. 2 illustrates a schematic diagram of a semiconductor device 20 according to another embodiment of the present disclosure;

FIG. 3A illustrates a schematic diagram of a semiconductor device 30 according to another embodiment of the present disclosure;

FIG. 3B illustrates a schematic diagram of a cross-sectional view of the semiconductor device 30 in FIG. 3A;

FIG. 4A illustrates a schematic diagram of a semiconductor device 40 according to another embodiment of the present disclosure;

FIG. 4B illustrates a schematic diagram of a cross-sectional view of the semiconductor device 40 in FIG. 4A;

FIG. 5 illustrates a schematic diagram of a semiconductor device 50 according to another embodiment of the present disclosure;

FIG. 6A illustrates a schematic diagram of a semiconductor device 60 according to another embodiment of the present disclosure;

FIG. 6B illustrates a schematic diagram of a substrate 610 of the semiconductor device 60 in FIG. 6A;

FIG. 7 illustrates a schematic diagram of a semiconductor device 70 according to another embodiment of the present disclosure;

FIG. 8 illustrates a schematic diagram of a semiconductor device 80 according to another embodiment of the present disclosure;

FIG. 9 illustrates a schematic diagram of the silicon base 111 of the substrate 110 in FIG. 1;

FIG. 10A illustrates a schematic diagram of a substrate 910A according to another embodiment of the present disclosure;

FIG. 10B illustrates a schematic diagram of a substrate 910B according to another embodiment of the present disclosure;

FIG. 10C illustrates a schematic diagram of a substrate 910C according to another embodiment of the present disclosure;

FIG. 10D illustrates a schematic diagram of a substrate 910D according to another embodiment of the present disclosure;

FIGS. 11A to 11G illustrate schematic diagrams of manufacturing processes of the semiconductor chip 100 of FIG. 1;

FIGS. 12A to 12L illustrate schematic diagrams of manufacturing processes of the substrate 610 in FIG. 6B;

FIGS. 13A to 13C illustrate manufacturing processes of a diamond layer DL according to an embodiment of the present disclosure;

FIGS. 14A to 141 illustrate manufacturing processes of the diamond layer DL according to another embodiment of the present disclosure; and

FIGS. 15A to 15H illustrate manufacturing processes of the diamond layer DL according to another embodiment of the present disclosure.

In the following detailed description, for purposes of explanation, numerous specific details are set forth in order to provide a thorough understanding of the disclosed embodiments. It will be apparent, however, that one or more embodiments can be practiced without these specific details. In other instances, well-known structures and devices are schematically shown in order to simplify the drawing.

### DETAILED DESCRIPTION

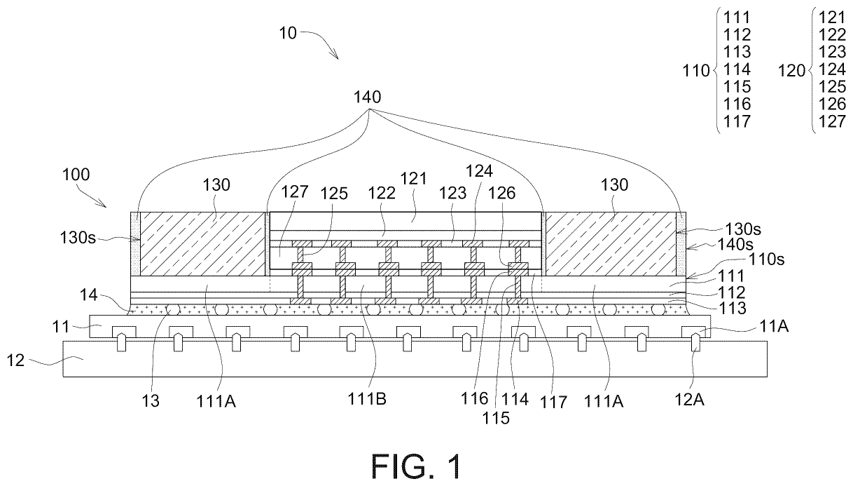

Referring to FIG. 1, FIG. 1 illustrates a schematic diagram of a semiconductor device 10 according to an embodiment of the present disclosure. The semiconductor device 10 includes a semiconductor chip 100, a first substrate 11, a second substrate 12, at least one electrical contact 13, and an encapsulation material such as an underfill 14 (which can also be a non-conductive paste or film). The semiconductor chip 100 is disposed on the first substrate 11 through a plurality of the electrical contacts 13 such as solder balls. The underfill 14 is disposed between the semiconductor chip 100 and the first substrate 11 and encapsulates the electrical contacts 13. The first substrate 11 is disposed between the second substrate 12 and the semiconductor chip 100. The first substrate 11 includes at least one LGA (Land grid array) pad 11A, and the second substrate 12 includes at least one contact pin 12A, wherein the first substrate 11 and the second substrate 12 are electrically connected with each other through the connection of the contact pin 12A and the LGA pad 11A. In another embodiment, the first substrate 11 and the second substrate can be connected through a plurality of solder balls such as BGA (Ball Grid Array) balls. This also applies to other similar structures disclosed herein and will not be repeated for brevity.

In an embodiment, the first substrate 11 is, for example, a laminate substrate. The electrical contact 13 is, for example, a solder ball, a conductive copper pillar, micro-bump, etc. The second substrate 12 is, for example, a PCB (printed circuit board).

As illustrated in FIG. 1, the semiconductor chip 100 includes a substrate 110, at least one memory component 120, at least one heat dissipation component 130 and a molding compound 140. The memory component 120 is disposed on the substrate 110. The heat dissipation component 130 is disposed on the substrate 110. The heat dissipation component 130 has a thermal conductivity greater than that of silicon. As a result, the heat dissipation component 130 may quickly conduct heat to the outside of the semiconductor device 10.

As illustrated in FIG. 1, the substrate 110 includes a silicon base 111, a FEOL (front-end-of-line) layer 112, a BEOL (back-end-of-line) layer 113, a plurality of first conductive contacts 114, a plurality of conductive vias 115, a plurality of second conductive contacts 116 and a dielectric layer 117. The substrate 110 is, for example, a processor such as a CPU (central processing unit) with at least one core and at least one cache memory (for example, L3 catch memory). In an embodiment, the substrate 110 is, for example, an ultra-thin CPU (only ˜30 μm thick), and the ultra-thin silicon has an effective TC which is far lower than that of bulk Si (˜140 W/m·K). In another embodiment, the first substrate 11 may be, for example, another memory component. The structures disclosed herein are particularly well suited for bonding of an “ultra-thin” device such as a SRAM (static random-access memory) or a logic which can be a low-power device or a high-power device on an “ultra-thin” high-power logic.

As illustrated in FIG. 1, the silicon base 111 is, for example, a portion of silicon wafer. At least one processor core 111A and at least one L3 cache 111B are formed in the silicon base 111. In the present embodiment, the heat generated by the processor core 111A may be quickly conducted through the heat dissipation component 130. The FEOL layer 112 is formed on the silicon base 111. The BEOL layer 113 is formed on the FEOL layer 112 and includes the first conductive contact 114 formed in the BEOL layer 113. The dielectric layer 117 is formed on the silicon base 111. The second conductive contacts 116 are formed in the dielectric layer 117, wherein the conductive vias 115 connect the second conductive contacts 116 and the first conductive contacts 114.

As illustrated in FIG. 1, the memory component 120 and the heat dissipation component 130 may be disposed side by side. The memory component 120 includes a silicon base 121, a FEOL layer 122, a BEOL layer 123, a plurality of first conductive contacts 124, a plurality of conductive vias 125, a plurality of second conductive contacts 126 and a dielectric layer 127. The memory component 120 is, for example, SRAM.

As illustrated in FIG. 1, the silicon base 121 is, for example, a portion of silicon wafer. The FEOL layer 122 is formed on the silicon base 121 and includes at least memory unit (not illustrated). The BEOL layer 123 is formed on the FEOL layer 122 and includes the first conductive contact 124 formed in the BEOL layer 123. The dielectric layer 127 is formed on the BEOL layer 123. The conductive vias 125 and the second conductive contacts 126 are formed in the dielectric layer 127, wherein the conductive vias 125 connect the second conductive contacts 126 and the first conductive contacts 124.

In the present embodiment, the memory component 120 and the substrate 110 are connected with each other. For example, the memory component 120 and the substrate 110 are directly connected with each other. The second conductive contacts 116 of the substrate 110 and the second conductive contacts 126 of the memory component 120 may be directly connected with each other, and the dielectric layer 117 of the substrate 110 and the dielectric layer 127 of the memory component 120 may be directly connected with each other using copper hybrid bonding techniques.

In an embodiment, the heat dissipation component 130 may be made of a high-thermal-conductivity (HTC) and low-coefficient-of-thermal-expansion (LCTE) material such as diamond, aluminum nitride, boron nitride, boron arsenide, silicon carbide, a suitable HTC and LCTE material such as a clad metal (e.g., copper/invar/copper), or a combination thereof. The heat dissipation component 130 may be made by a high-quality microwave-plasma chemical vapor deposition (MPCVD) technique or other suitable means to form different thicknesses of diamond. In an embodiment, diamond's TC (thermal-conductivity) may be up to 2400 W/m·K.

As illustrated in FIG. 1, the heat dissipation component 130 may be directly disposed (or bonded) on the silicon base 111 of the substrate 110. In another embodiment, the heat dissipation component 130 may be disposed on the silicon base 111 of the substrate 110 through an oxide layer (not illustrated) using, for example, an oxide bonding technique, wherein the oxide layer is disposed between the heat dissipation component 130 and the silicon base 111 of the substrate 110.

As illustrated in FIG. 1, the molding compound 140 is formed between the memory component 120 and the heat dissipation component 130, and covers a lateral surface 130s of each heat dissipation component 130. The molding compound 140 may include, for example, a Novolac-based resin, an epoxy-based resin, a silicone-based resin, or a suitable encapsulant. Suitable fillers also can be included, such as powdered SiO₂. The molding compound 140 may be applied using any of a number of molding techniques, such as compression molding, injection molding, or transfer molding. In addition, the molding compound 140 has a lateral surface 140s, and the substrate 110 has a lateral surface 110s, wherein the lateral surface 140s of the molding compound and the lateral surface 110s of the substrate 110 are flushed with each other.

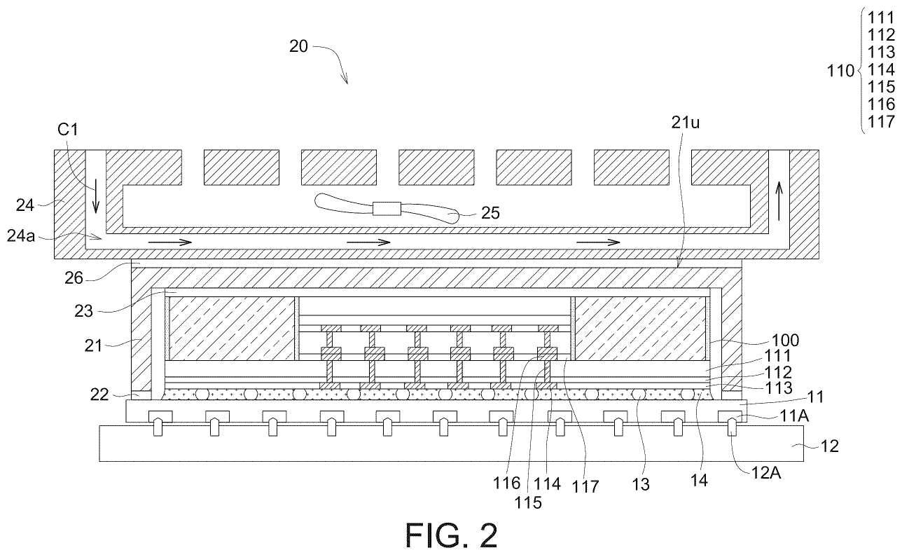

Referring to FIG. 2, FIG. 2 illustrates a schematic diagram of a semiconductor device 20 according to another embodiment of the present disclosure. The semiconductor device 20 includes the semiconductor chip 100, the first substrate 11, the second substrate 12, at least one contact 13, the underfill 14, a heat spreader 21, a first adhesive 22, a second adhesive 23, a first cooling component 24, a second cooling component 25 and a third adhesive 26.

The semiconductor device 20 includes the features the same as or similar to those of the semiconductor device 10 with at least one difference being the semiconductor device 20 further includes the heat spreader 21, the first adhesive 22, the second adhesive 23, the first cooling component 24, the second cooling component 25 and the third adhesive 26.

As illustrated in FIG. 2, the heat spreader 21 including a vapor chamber (or a structure made of a high-TC material such as diamond or a high-TC material and a vapor chamber) which covers the memory component 120 and the heat dissipation component 130 and has an upper surface 21u. Furthermore, the memory component 120 and the heat dissipation component 130 are disposed within the vapor chamber. The first cooling component 24 is disposed on the upper surface 21u of the heat spreader 21 and has a fluid channel 24a. The heat spreader 21 is disposed on the first substrate 11 through the first adhesive 22, wherein the first adhesive 22 is disposed between the heat spreader 21 and the first substrate 11. The heat spreader 21 is disposed on the semiconductor chip 100 through the second adhesive 23, wherein the second adhesive 23 is disposed between the heat spreader 21 and the semiconductor chip 100. The first cooling component 24 is disposed on the heat spreader 21 and is thermally coupled to the second cooling component 25, wherein the second cooling component 25 is disposed between the first cooling component 24 and an external heat exchanger. In an embodiment, the first adhesive 22, the second adhesive 23 and the third adhesive 26 may be formed of, for example, a high-TC TIM (thermal interface material) or a suitable high-TC material. In an embodiment, the second cooling component 25 includes, for example, a fan, a heat exchanger, a direct-to-chip liquid cooling or direct-to-chip cooling or liquid immersion cooling device cooling device or a combination thereof. Similar statement can be made for other similar structures and will not be repeated for brevity.

In another embodiment, the semiconductor device 20 further includes a high-TC plate (not illustrated) disposed between the third adhesive 26 and the heat spreader 21.

As illustrated in FIG. 2, the semiconductor chip 100 includes the substrate 110, at least one memory component 120, at least one heat dissipation component 130 and the molding compound 140. The memory component 120 is disposed on the substrate 110. The heat dissipation component 130 is disposed on the substrate 110. The heat dissipation component 130 has a thermal conductivity greater than that of silicon. As a result, the heat dissipation component 130 may quickly conduct heat to the outside of the semiconductor device 20.

As illustrated in FIG. 2, the substrate 110 includes the silicon base 111, the FEOL layer 112, the BEOL layer 113, a plurality of the first conductive contacts 114, a plurality of the conductive vias 115, a plurality of the second conductive contacts 116 and the dielectric layer 117. The silicon base 111 is, for example, a portion of silicon wafer. At least one processor core 111A and at least one L3 cache 111B are formed in the silicon base 111. In the present embodiment, the heat generated by the processor core 111A may be quickly conducted through the heat dissipation component 130. The heat generated by the processor core 111A may be quickly conducted to the first cooling component 24 through the heat dissipation component 130 and the heat spreader 21. The heat may be conducted to a coolant C1 within the fluid channel 24a and transmitted to the outside of the semiconductor device 20 through the coolant C1.

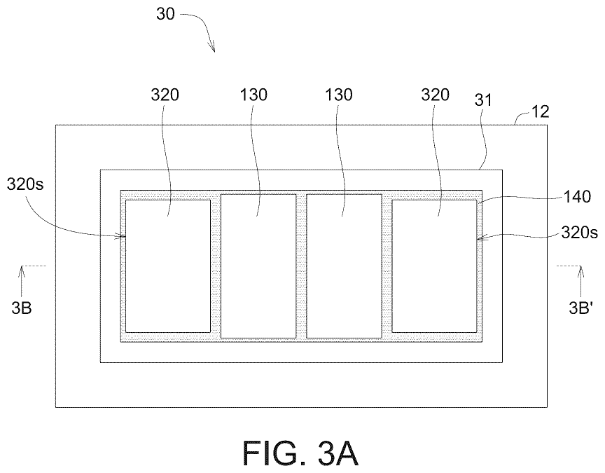

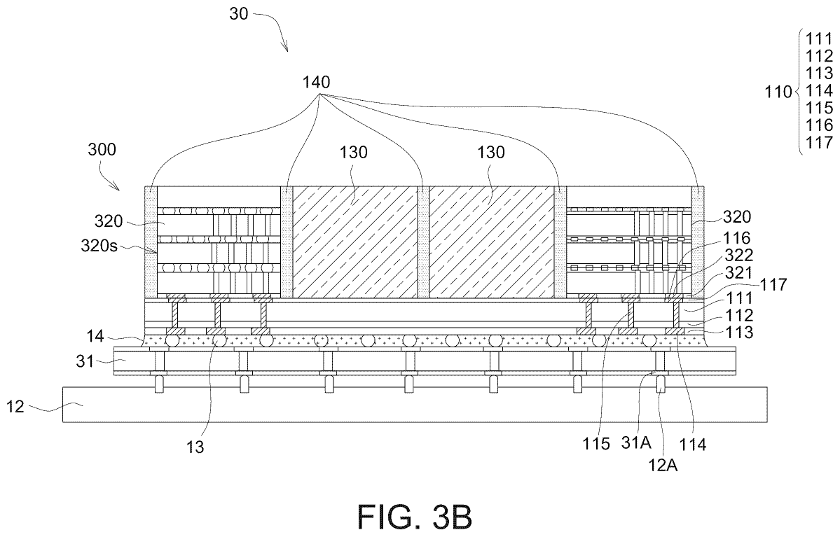

Referring to FIGS. 3A and 3B, FIG. 3A illustrates a schematic diagram of a semiconductor device 30 according to another embodiment of the present disclosure, whereas FIG. 3B illustrates a schematic diagram of a cross-sectional view of the semiconductor device 30 in FIG. 3A along a direction 3B-3B′.

As illustrated in FIG. 3B, the semiconductor device 30 includes the semiconductor chip 300, the first substrate 31, the second substrate 12, at least one electrical contact 13 and the underfill 14. The semiconductor chip 300 is disposed on the substrate 31 through a plurality of the electrical contacts 13. The underfill 14 is disposed between the semiconductor chip 300 and the first substrate 31 and encapsulates the electrical contacts 13. The first substrate 31 is disposed between the second substrate 12 and the semiconductor chip 300. The first substrate 31 includes at least one pad 31A, and the second substrate 12 includes at least one contact pin 12A, wherein the first substrate 31 and the second substrate 12 are electrically connected with each other through the connection of the contact pin 12A and the pad 31A. In the present embodiment, the first substrate 31 is, for example, an interposer such as a silicon interposer, a glass interposer, a glass substrate, an interposer made of a high-TC material, or a combination thereof. In another embodiment, the first substrate can be a combination of an interposer and a laminate substrate.

As illustrated in FIG. 3B, the semiconductor chip 300 includes the substrate 110, at least one memory component 320, at least one heat dissipation component 130 and the molding compound 140. The memory components 320 are disposed on the substrate 110. The heat dissipation components 130 are disposed on the substrate 110. The heat dissipation component 130 has a thermal conductivity greater than that of silicon. As a result, the heat dissipation component 130 may quickly conduct heat to the outside of the semiconductor device 30.

As illustrated in FIG. 3B, in the present embodiment, at least one heat dissipation component 130 is disposed between the memory components 320. The molding compound 140 is formed between the memory component 320 and the heat dissipation component 130, and covers a lateral surface 320s of each memory component 320.

As illustrated in FIG. 3B, each memory component 320 is, for example, a high-bandwidth-memory (HBM) DRAM stack or a die stack structure embodying memory functions (or both memory and logic functions). The memory component 320 at least includes a dielectric layer 321 and at least one conductive pad 322, wherein the conductive pad 322 is formed in the dielectric layer 321. The memory component 320 and the substrate 110 are directly connected with each other. The second conductive contacts 116 of the substrate 110 and the conductive pad 322 of the memory component 320 may be directly connected with each other, and the dielectric layer 117 of the substrate 110 and the dielectric layer 321 of the memory component 320 may be directly connected with each other using copper hybrid bonding techniques.

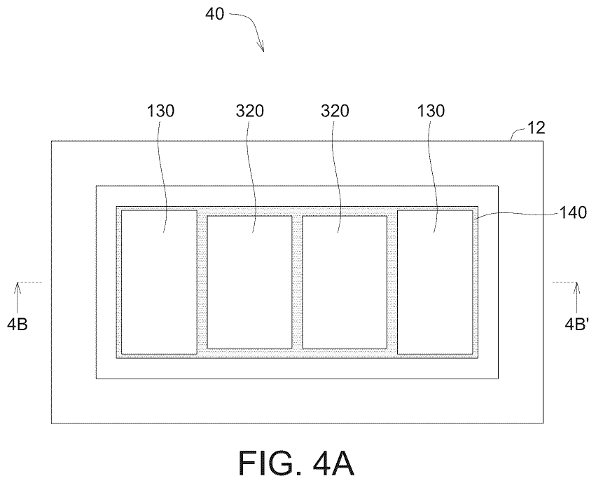

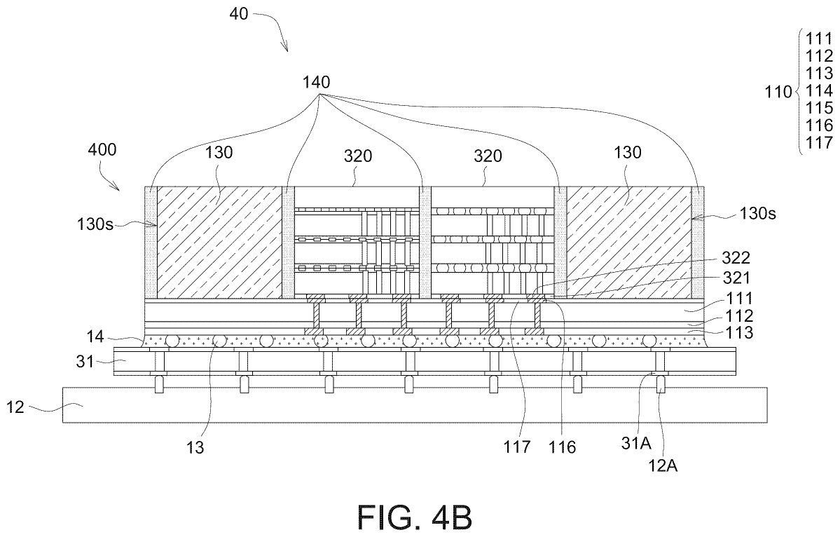

Referring to FIGS. 4A and 4B, FIG. 4A illustrates a schematic diagram of a semiconductor device 40 according to another embodiment of the present disclosure, whereas FIG. 4B illustrates a schematic diagram of a cross-sectional view of the semiconductor device 40 in FIG. 4A along a direction 4B-4B′.

The semiconductor device 40 includes the semiconductor chip 400, the first substrate 31, the second substrate 12, at least one electrical contact 13 and the underfill 14. The semiconductor chip 400 is disposed on the substrate 31 through a plurality of the electrical contacts 13. The underfill 14 is disposed between the semiconductor chip 400 and the first substrate 31 and encapsulates the electrical contacts 13. The first substrate 31 is disposed between the second substrate 12 and the semiconductor chip 400. The first substrate 31 includes at least one pad 31A, and the second substrate 12 includes at least one contact pin 12A, wherein the first substrate 31 and the second substrate 12 are electrically connected with each other through the connection of the contact pin 12A and the pad 31A. In the present embodiment, the first substrate 31 is, for example, an interposer such as a silicon interposer, a glass interposer, a glass substrate, an interposer made of a high-TC material, or a combination thereof. In another embodiment, the first substrate can be a combination of an interposer and a laminate substrate.

As illustrated in FIG. 4B, the semiconductor chip 400 includes the substrate 110, at least one memory component 320, at least one heat dissipation component 130 and the molding compound 140. The memory components 320 are disposed on the substrate 110. The heat dissipation components 130 are disposed on the substrate 110. The heat dissipation component 130 has a thermal conductivity greater than that of silicon. As a result, the heat dissipation component 130 may quickly conduct heat to the outside of the semiconductor device 40.

As illustrated in FIG. 4B, in the present embodiment, at least one the memory component 320 is disposed between the heat dissipation components 130. The molding compound 140 is formed between the memory components 320, between the heat dissipation component 130 and the memory component 320, and covers a lateral surface 130s of each heat dissipation component 130.

As illustrated in FIG. 4B, each memory component 320 is, for example, a HBM or a die stack structure embodying memory functions (or both memory and logic functions). The memory component 320 at least includes the dielectric layer 321 and at least one conductive pad 322, wherein the conductive pad 322 is formed in the dielectric layer 321. The memory component 320 and the substrate 110 are directly connected with each other. The second conductive contacts 116 of the substrate 110 and the conductive pad 322 of the memory component 320 may be directly connected with each other, and the dielectric layer 117 of the substrate 110 and the dielectric layer 321 of the memory component 320 may be directly connected with each other using copper hybrid bonding techniques.

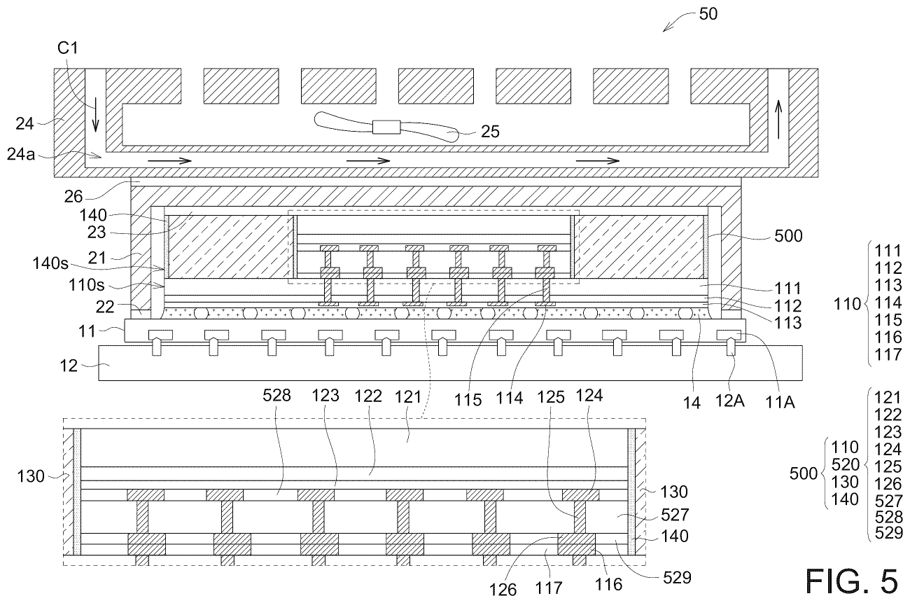

Referring to FIG. 5, FIG. 5 illustrates a schematic diagram of a semiconductor device 50 according to another embodiment of the present disclosure. The semiconductor device 50 includes the semiconductor chip 500, the first substrate 11, the second substrate 12, at least one contact 13, the underfill 14, the heat spreader 21, the first adhesive 22, the second adhesive 23, the first cooling component 24, the second cooling component 25 and the third adhesive 26.

The semiconductor device 50 includes the features the same as or similar to those of the semiconductor device 10 with at least one difference being that the semiconductor device 50 further includes the heat spreader 21, the first adhesive 22, the second adhesive 23, the first cooling component 24, the second cooling component 25 and the third adhesive 26.

As illustrated in FIG. 5, the heat spreader 21 including the vapor chamber (or a structure made of a high-TC material such as diamond or a high-TC material and a vapor chamber) which covers the memory component 520 and the heat dissipation component 130 and has the upper surface 21u. Furthermore, the memory component 520 and the heat dissipation component 130 are disposed within the vapor chamber. The first cooling component 24 is disposed on the upper surface 21u of the heat spreader 21 and has the fluid channel 24a. The heat spreader 21 is disposed on the first substrate 11 through the first adhesive 22, wherein the first adhesive 22 is disposed between the heat spreader 21 and the first substrate 11. The heat spreader 21 is disposed on the semiconductor chip 500 through the second adhesive 23, wherein the third adhesive 26 is disposed between the heat spreader 21 and the first cooling component 24. The first cooling component 24 is disposed on the heat spreader 21 and is thermally coupled to the second cooling component 25. In an embodiment, the first adhesive 22, the second adhesive 23 and the third adhesive 26 may be formed of, for example, a high-TC TIM or a suitable high-TC material. In an embodiment, the second cooling component 25 includes, for example, a fan, a heat exchanger, a direct-to-chip liquid cooling device, a liquid immersion cooling device or a combination thereof.

In another embodiment, the semiconductor device 50 further includes a high-TC plate (not illustrated) disposed between the third adhesive 26 and the heat spreader 21.

As illustrated in FIG. 5, the semiconductor chip 500 includes the substrate 110, at least one memory component 520, at least one heat dissipation component 130 and the molding compound 140. The memory component 520 is disposed on the substrate 110. The heat dissipation component 130 is disposed on the substrate 110. The heat dissipation component 130 has a thermal conductivity greater than that of silicon. As a result, the heat dissipation component 130 may quickly conduct heat to the outside of the semiconductor device 50.

As illustrated in FIG. 5, the memory component 520 and the heat dissipation component 130 may be disposed side by side. The memory component 520 includes the silicon base 121, the FEOL layer 122, the BEOL layer 123, a plurality of the first conductive contacts 124, a plurality of the conductive vias 125, a plurality of the second conductive contacts 126 and the dielectric layer 127. The memory component 520 is, for example, SRAM.

In an embodiment, the heat dissipation component 130 may be made of a HTC and LCTE material such as diamond, aluminum nitride, boron nitride, boron arsenide, silicon carbide, a suitable HTC and LCTE material such as a clad metal (e.g., copper/invar/copper), or a combination thereof. The heat dissipation component 130 may be made by a high-quality microwave-plasma chemical vapor deposition (MPCVD) technique or other suitable means to form different thicknesses of diamond. In an embodiment, diamond's TC (thermal-conductivity) may be up to 2400 W/m·K.

As illustrated in FIG. 5, the heat dissipation component 130 may be directly disposed (or bonded) on the substrate 110. In another embodiment, the heat dissipation component 130 may be disposed on the substrate 110 through an oxide layer (not illustrated) using, for example, an oxide bonding technique, wherein the oxide layer is disposed between the heat dissipation component 130 and the substrate 110.

As illustrated in FIG. 5, the molding compound 140 is formed between the memory component 520 and the heat dissipation component 130, and covers the lateral surface 130s of each heat dissipation component 130. The molding compound 140 may include, for example, a Novolac-based resin, an epoxy-based resin, a silicone-based resin, or a suitable encapsulant. Suitable fillers also can be included, such as powdered SiO₂. The molding compound 140 may be applied using any of a number of molding techniques, such as compression molding, injection molding, or transfer molding. In addition, the molding compound 140 has the lateral surface 140s, and the substrate 110 has the lateral surface 110s, wherein the lateral surface 140s of the molding compound and the lateral surface 110s of the substrate 110 are flushed with each other.

As illustrated in FIG. 5, the memory component 520 includes the silicon base 121, the FEOL layer 122, the BEOL layer 123, a plurality of the first conductive contacts 124, a plurality of the conductive vias 125, a plurality of the second conductive contacts 126, a high-TC layer 527 such as a diamond layer (or an aluminum nitride layer), a first dielectric layer 528 and a second dielectric layer 529. The memory component 520 is, for example, SRAM.

As illustrated in FIG. 5, the silicon base 121 is, for example, a portion of silicon wafer. The FEOL layer 122 is formed on the silicon base 121 and includes at least one memory unit (not illustrated). The BEOL layer 123 is formed on the FEOL layer 122. The first dielectric layer 528 and the second dielectric layer 529 are formed on adjacent two sides of the diamond layer 527 respectively. The first conductive contacts 124 are formed in the first dielectric layer 528, and the second conductive contacts 126 are formed in the second dielectric layer 529. The first conductive contacts 124 may be electrically connected with the BEOL layer 123, and electrically connected with the second conductive contact 126 through the conductive vias 125. The conductive via 125 is, for example, TDV (through-diamond via).

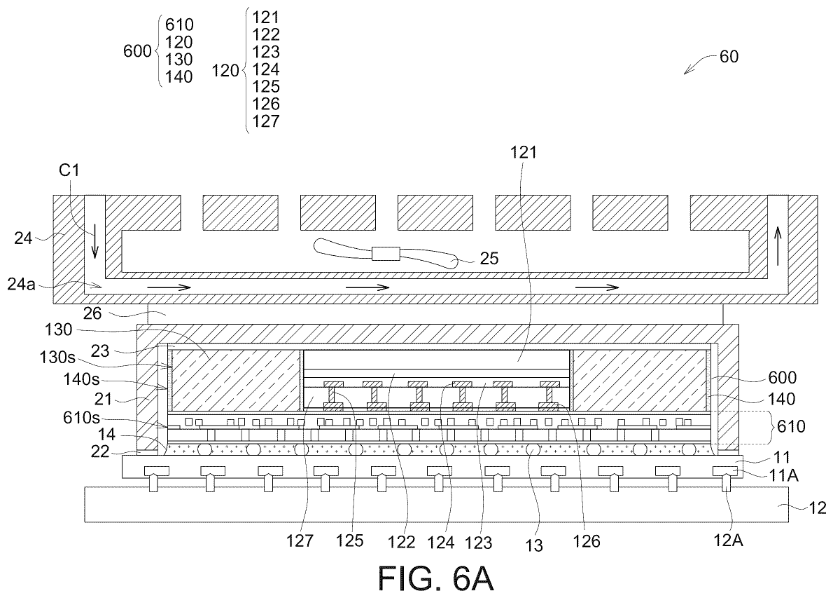

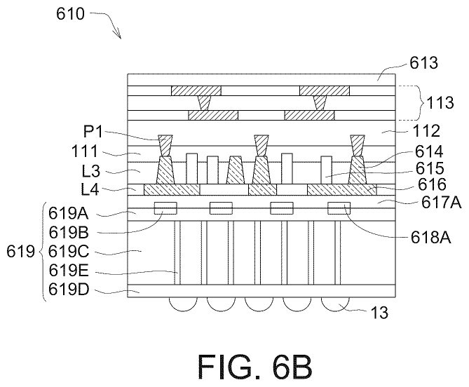

Referring to FIGS. 6A and 6B, FIG. 6A illustrates a schematic diagram of a semiconductor device 60 according to another embodiment of the present disclosure, whereas FIG. 6B illustrates a schematic diagram of a substrate 610 of the semiconductor device 60 in FIG. 6A. The semiconductor device 60 includes a semiconductor chip 600, the first substrate 11, the second substrate 12, at least one contact 13, and the underfill 14. The semiconductor chip 600 is disposed on the first substrate 11 through a plurality of the electrical contacts 13. The underfill 14 is disposed between the semiconductor chip 600 and the first substrate 11 and encapsulates the electrical contacts 13. The first substrate 11 is disposed between the second substrate 12 and the semiconductor chip 600. The first substrate 11 includes at least one LGA pad 11A, and the second substrate 12 includes at least one contact pin 12A, wherein the first substrate 11 and the second substrate 12 are electrically connected with each other through the connection of the contact pin 12A and the LGA pad 11A.

In an embodiment, the first substrate 11 is, for example, a laminate substrate. The electrical contact 13 is, for example, solder ball, copper pillar, micro-bump, etc. The second substrate 12 is, for example, a PCB. In another embodiment, the first substrate 11 is an interposer such as a silicon interposer, a glass interposer, a glass substrate, an interposer made of a high-TC material, or a combination thereof. In another embodiment, the first substrate can be a combination of an interposer and a laminate substrate.

As illustrated in FIG. 6A, the semiconductor chip 600 includes a substrate 610, at least one memory component 120, at least one heat dissipation component 130 and a molding compound 140. The memory component 120 is disposed on the substrate 610. The heat dissipation component 130 is disposed on the substrate 610. The heat dissipation component 130 has a thermal conductivity greater than that of silicon. As a result, the heat dissipation component 130 may quickly conduct heat to the outside of the semiconductor device 60.

As illustrated in FIG. 6A, the memory component 120 and the heat dissipation component 130 may be disposed side by side. The memory component 120 includes the silicon base 121, the FEOL layer 122, the BEOL layer 123, a plurality of the first conductive contacts 124, a plurality of the conductive vias 125, a plurality of the second conductive contacts 126 and the dielectric layer 127. The memory component 120 is, for example, SRAM.

In an embodiment, the heat dissipation component 130 may be made of a HTC and LCTE material such as diamond, aluminum nitride, boron nitride, boron arsenide, silicon carbide, a suitable HTC and LCTE material such as a clad metal (e.g., copper/invar/copper), or a combination thereof. The heat dissipation component 130 may be made by a high-quality microwave-plasma chemical vapor deposition (MPCVD) technique or other suitable means to form different thicknesses of diamond. In an embodiment, diamond's TC (thermal-conductivity) may be up to 2400 W/m·K.

As illustrated in FIG. 6A, the heat dissipation component 130 may be directly disposed (or bonded) on the substrate 610. In another embodiment, the heat dissipation component 130 may be disposed on the substrate 610 through an oxide layer (not illustrated) using, for example, an oxide bonding technique, wherein the oxide layer is disposed between the heat dissipation component 130 and the substrate 610.

As illustrated in FIG. 6A, the molding compound 140 is formed between the memory component 120 and the heat dissipation component 130, and covers the lateral surface 130s of each heat dissipation component 130. The molding compound 140 may include, for example, a Novolac-based resin, an epoxy-based resin, a silicone-based resin, or a suitable encapsulant. Suitable fillers also can be included, such as powdered SiO₂. The molding compound 140 may be applied using any of a number of molding techniques, such as compression molding, injection molding, or transfer molding. In addition, the molding compound 140 has the lateral surface 140s, and the substrate 610 has a lateral surface 610s, wherein the lateral surface 140s of the molding compound and the lateral surface 610s of the substrate 610 are flushed with each other.

As illustrated in FIG. 6B, the substrate 610 is the substrate with a backside power delivery network (BSPDN). Furthermore, the substrate 610 includes the silicon base 111, the FEOL layer 112, the BEOL layer 113 (which can consist of a local interconnect layer and an intermediate interconnect layer), a RDL (redistribution layers) 613, at least one power rail (power rail layer) P1, at least one first conductive via 614, at least one second conductive via 615, at least one power trace (power delivery and signaling layer) 616, a silicon layer L3, a dielectric layer L4 (which in conjunction with 616 can form the BEOL global interconnect layer), a RDL 617A, at least one conductive pad 618A and an interposer 619. The power rail P1 formed in the silicon base 111 is coupled electrically to the FEOL layer 112. The first conductive via 614 is connected to the power rail P1 through the silicon layer L3. The second conductive via 615 is formed within the silicon layer L3. The dielectric layer L4 is formed on the silicon layer L3. The power trace 616 is formed in the dielectric layer L4 and electrically connected to the first conductive via 614 and the second conductive via 615. The RDL 617A is formed on the dielectric layer L4 and electrically connected to the power trace 616. The conductive pad 618A is formed in the RDL 617A. In addition, the FEOL layer 112 includes a plurality of transistors (not illustrated), and the transistor includes, for example, a fin FET (field-effect transistor) structure, a nano-sheet structure, or a GAA (gate-all-around) structure.

As illustrated in FIG. 6B, the interposer 619 is a HTC and LCTE interposer disposed adjacent to and electrically and thermally coupled to the power supply (signaling) layer, wherein the HTC and LCTE interposer may be made of diamond, aluminum nitride, boron nitride, boron arsenide, a suitable HTC and LCTE material, or a combination thereof. Furthermore, the interposer 619 includes a RDL 619A, at least one conductive pad 619B, a diamond layer 619C (or a HTC and LCTE layer), a RDL 619D and at least one TDV 619E. The RDL 619A and the RDL 619D are formed adjacent two sides of the diamond layer 619C respectively. The TDV 619E is formed within the diamond layer 619C, and connects the RDL 619A and the RDL 619D. The conductive pad 619B is formed within the RDL 619A. The interposer 619 connects the RDL 617A through the connection of the conductive pad 618A and the conductive pad 619B. In the present embodiment, the memory component 120 is disposed on the substrate 610 encompassing the HTC and LCTE material.

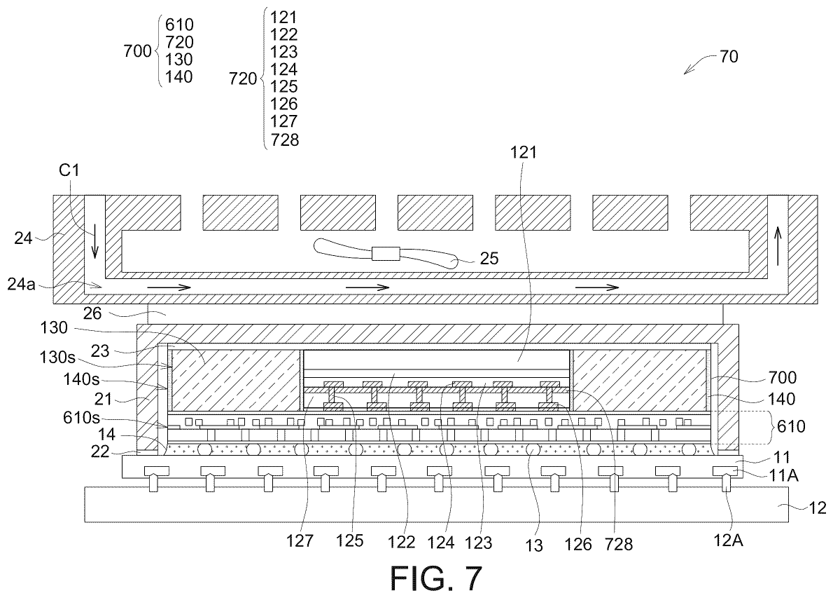

Referring to FIG. 7, FIG. 7 illustrates a schematic diagram of a semiconductor device 70 according to another embodiment of the present disclosure.

As illustrated in FIG. 7, the semiconductor device 70 includes a semiconductor chip 700, the first substrate 11, the second substrate 12, at least one contact 13, and the underfill 14. The semiconductor chip 700 is disposed on the first substrate 11 through a plurality of the electrical contacts 13. The underfill 14 is disposed between the semiconductor chip 700 and the first substrate 11 and encapsulates the electrical contacts 13. The first substrate 11 is disposed between the second substrate 12 and the semiconductor chip 700. The first substrate 11 includes at least one LGA pad 11A, and the second substrate 12 includes at least one contact pin 12A, wherein the first substrate 11 and the second substrate 12 are electrically connected with each other through the connection of the contact pin 12A and the LGA pad 11A.

As illustrated in FIG. 7, the semiconductor chip 700 includes the substrate 610, at least one memory component 720, at least one heat dissipation component 130 and a molding compound 140. The memory component 720 is disposed on the substrate 610. The heat dissipation component 130 is disposed on the substrate 610. The heat dissipation component 130 has a thermal conductivity greater than that of silicon. As a result, the heat dissipation component 130 may quickly conduct heat to the outside of the semiconductor device 70.

In an embodiment, the heat dissipation component 130 may be made of a HTC and LCTE material such as diamond, aluminum nitride, boron nitride, boron arsenide, silicon carbide, a suitable HTC and LCTE material such as a clad metal (e.g., copper/invar/copper), or a combination thereof. The heat dissipation component 130 may be made by a high-quality microwave-plasma chemical vapor deposition (MPCVD) technique or other suitable means to form different thicknesses of diamond. In an embodiment, diamond's TC (thermal-conductivity) may be up to 2400 W/m·K.

As illustrated in FIG. 7, the heat dissipation component 130 may be directly disposed (or bonded) on the substrate 610. In another embodiment, the heat dissipation component 130 may be disposed on the substrate 610 through an oxide layer (not illustrated) using, for example, an oxide bonding technique, wherein the oxide layer is disposed between the heat dissipation component 130 and the substrate 610.

As illustrated in FIG. 7, the molding compound 140 is formed between the memory component 720 and the heat dissipation component 130, and covers the lateral surface 130s of each heat dissipation component 130. The molding compound 140 may include, for example, a Novolac-based resin, an epoxy-based resin, a silicone-based resin, or a suitable encapsulant. Suitable fillers also can be included, such as powdered SiO₂. The molding compound 140 may be applied using any of a number of molding techniques, such as compression molding, injection molding, or transfer molding. In addition, the molding compound 140 has the lateral surface 140s, and the substrate 610 has a lateral surface 610s, wherein the lateral surface 140s of the molding compound and the lateral surface 610s of the substrate 610 are flushed with each other.

As illustrated in FIG. 7, the memory component 720 and the heat dissipation component 130 may be disposed side by side. The memory component 720 includes the silicon base 121, the FEOL layer 122, the BEOL layer 123, a plurality of the first conductive contacts 124, a plurality of the conductive vias 125, a plurality of the second conductive contacts 126, the dielectric layer 127 and a thermal isolation layer 728. The memory component 720 is, for example, SRAM.

The memory component 720 includes the features the same as or similar to those of the memory component 120 with at least one difference being that the thermal isolation layer 728 of the memory component 720 is formed between the BEOL layer 123 and the dielectric layer 127.

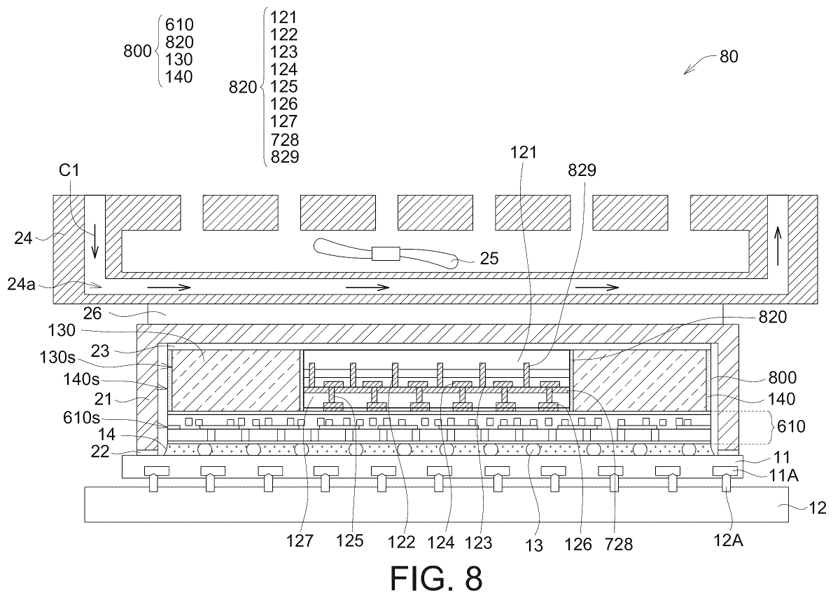

Referring to FIG. 8, FIG. 8 illustrates a schematic diagram of a semiconductor device 80 according to another embodiment of the present disclosure.

As illustrated in FIG. 8, the semiconductor device 80 includes a semiconductor chip 800, the first substrate 11, the second substrate 12, at least one contact 13 and the underfill 14. The semiconductor chip 800 is disposed on the first substrate 11 through a plurality of the electrical contacts 13. The underfill 14 is disposed between the semiconductor chip 800 and the first substrate 11 and encapsulates the electrical contacts 13. The first substrate 11 is disposed between the second substrate 12 and the semiconductor chip 800. The first substrate 11 includes at least one LGA pad 11A, and the second substrate 12 includes at least one contact pin 12A, wherein the first substrate 11 and the second substrate 12 are electrically connected with each other through the connection of the contact pin 12A and the LGA pad 11A.

As illustrated in FIG. 8, the semiconductor chip 800 includes a substrate 610, at least one memory component 820, at least one heat dissipation component 130 and a molding compound 140. The memory component 820 is disposed on the substrate 610. The heat dissipation component 130 is disposed on the substrate 610. The heat dissipation component 130 has a thermal conductivity greater than that of silicon. As a result, the heat dissipation component 130 may quickly conduct heat to the outside of the semiconductor device 80.

In an embodiment, the heat dissipation component 130 may be made of a HTC and LCTE material such as diamond, aluminum nitride, boron nitride, boron arsenide, silicon carbide, a suitable HTC and LCTE material such as a clad metal (e.g., copper/invar/copper), or a combination thereof. The heat dissipation component 130 may be made by a high-quality microwave-plasma chemical vapor deposition (MPCVD) technique or other suitable means to form different thicknesses of diamond. In an embodiment, diamond's TC (thermal-conductivity) may be up to 2400 W/m·K.

As illustrated in FIG. 8, the heat dissipation component 130 may be directly disposed (or bonded) on the substrate 610. In another embodiment, the heat dissipation component 130 may be disposed on the substrate 610 through an oxide layer (not illustrated) using, for example, an oxide bonding technique, wherein the oxide layer is disposed between the heat dissipation component 130 and the substrate 610.

As illustrated in FIG. 8, the molding compound 140 is formed between the memory component 820 and the heat dissipation component 130, and covers the lateral surface 130s of each heat dissipation component 130. The molding compound 140 may include, for example, a Novolac-based resin, an epoxy-based resin, a silicone-based resin, or a suitable encapsulant. Suitable fillers also can be included, such as powdered SiO₂. The molding compound 140 may be applied using any of a number of molding techniques, such as compression molding, injection molding, or transfer molding. In addition, the molding compound 140 has the lateral surface 140s, and the substrate 610 has a lateral surface 610s, wherein the lateral surface 140s of the molding compound and the lateral surface 610s of the substrate 610 are flushed with each other.

As illustrated in FIG. 8, the memory component 820 and the heat dissipation component 130 may be disposed side by side. The memory component 820 includes the silicon base 121, the FEOL layer 122, the BEOL layer 123, a plurality of the first conductive contacts 124, a plurality of the conductive vias 125, a plurality of the second conductive contacts 126, the dielectric layer 127, the thermal isolation layer 728 and at least one thermal via 829. The memory component 820 is, for example, SRAM.

The memory component 820 includes the features the same as or similar to those of the memory component 720 with at least one difference being that the thermal via 829 extends to the silicon base 121 from the thermal isolation layer 728 through the FEOL layer 122 and the BEOL layer 123. (it makes sense only when thermal vias are coupled with heat spreading layers).

Referring to FIG. 9, FIG. 9 illustrates a schematic diagram of the silicon base 111 of the substrate 110 in FIG. 1. The substrate 110 includes a processor core 111A, a L3 cache 111B and a thermal metamaterial structure 111C. The L3 cache 111B is disposed adjacent to the processor core 111A. The thermal metamaterial structure 111C is disposed between the processor core 111A and the L3 cache 111B and between the L3 cache 111B and the memory component 120 to minimize thermal cross-talks, respectively, between the processor core and the L3 cache and between the L3 cache and the memory component 120 (illustrated in FIG. 1).

As illustrated in FIG. 9, the thermal metamaterial structure 111C is a thermal-guiding ring. The thermal metamaterial structure 111C includes a first layer 111C1, a second layer 111C2 and a third layer 111C3. The first layer 111C1 has a first thermal conductivity. The second layer 111C2 has a second thermal conductivity and surrounds the first layer 111C1. The third layer 111C3 has a third thermal conductivity and surrounds the second layer 111C2. The second thermal conductivity is greater than the first thermal conductivity, and the first thermal conductivity is greater than the third thermal conductivity. In an embodiment, the first layer 111C1 is formed of silicon, the second layer 111C2 is formed of graphene, and the third layer 111C3 is formed of silicon dioxide.

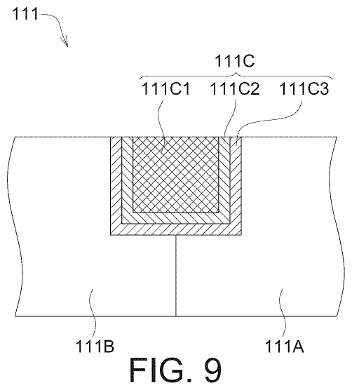

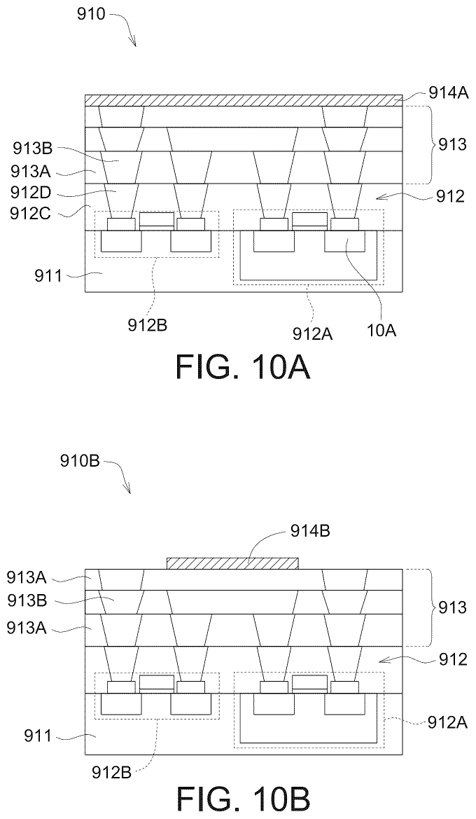

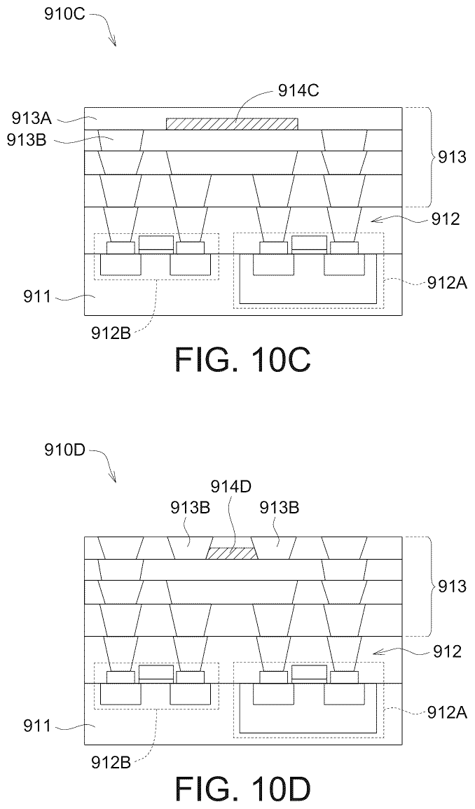

Referring to FIG. 10A, FIG. 10A illustrates a schematic diagram of a substrate 910A according to another embodiment of the present disclosure. The substrate 910A includes a silicon base 911, a FEOL layer 912, a BEOL layer 913 and a thermal component 914A shown atop the BEOL layer 913 (another thermal component 914A can also appear inside the BEOL layer 913 and/or in the FEOL layer 912). The FEOL layer 912 is formed on the silicon base 911, and includes a plurality of transistors 912A and 912B, a dielectric layer 912C and at least one conductive via 912D. The transistors 912A and 912B are formed in the silicon base 911 and the dielectric layer 912C. The conductive vias 912D are electrically connected with the transistors 912A and 912B through the dielectric layer 912C. The BEOL layer 913 includes a plurality of dielectric layers 913A and a plurality of conductive vias 913B. The dielectric layers 913A are stacked one on top of the other each other, and each conductive via 913B is formed in the corresponding dielectric layer 913A and electrically connected with the corresponding conductive vias 913B. The thermal component 914A is formed over the BEOL layer 913. Furthermore, the thermal component 914A is formed the entirety of an upper surface of the topmost dielectric layer 913A of the BEOL layer 913. The thermal component 914A is, for example, a thermal Isolation structure or a heat spreading structure.

Referring to FIG. 10B, FIG. 10B illustrates a schematic diagram of a substrate 910B according to another embodiment of the present disclosure. The substrate 910B includes the silicon base 911, the FEOL layer 912, the BEOL layer 913 and a thermal component 914B. The substrate 910B includes the features the same as or similar to those of the substrate 910A with at least one difference being that the thermal component 914B is formed on a portion of an upper surface of the topmost dielectric layer 913A of the BEOL layer 913 (or inside the BEOL layer 913, in the FEOL layer 912 or in both the BEOL and FEOL layers). The thermal component 914B is, for example, a thermal Isolation structure or a heat spreading structure.

Referring to FIG. 10C, FIG. 10C illustrates a schematic diagram of a substrate 910C according to another embodiment of the present disclosure. The substrate 910C includes the silicon base 911, the FEOL layer 912, the BEOL layer 913 and a thermal component 914C. The substrate 910C includes the features the same as or similar to those of the substrate 910B with at least one difference being that the thermal component 914C is covered by the dielectric layer 913A of the BEOL layer 913.

Referring to FIG. 10D, FIG. 10D illustrates a schematic diagram of a substrate 910D according to another embodiment of the present disclosure. The substrate 910D includes the silicon base 911, the FEOL layer 912, the BEOL layer 913 and a thermal component 914D. The substrate 910D includes the features the same as or similar to that of the substrate 910C with at least one difference being that the thermal component 914D is located between adjacent two of the conductive vias 913B and may be in contact with the adjacent two of the conductive vias 913B.

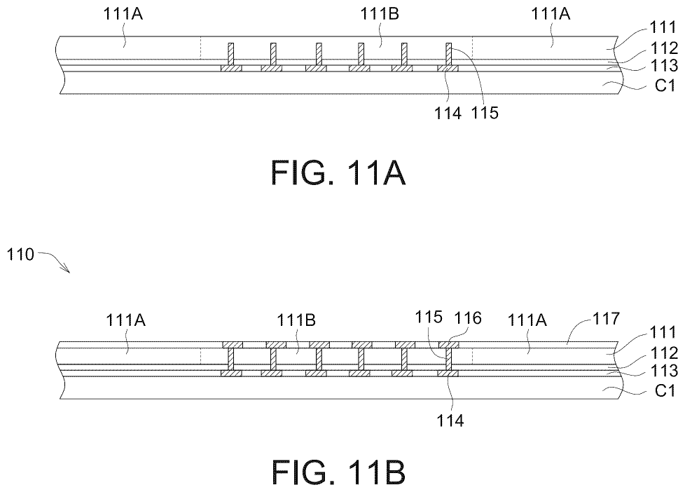

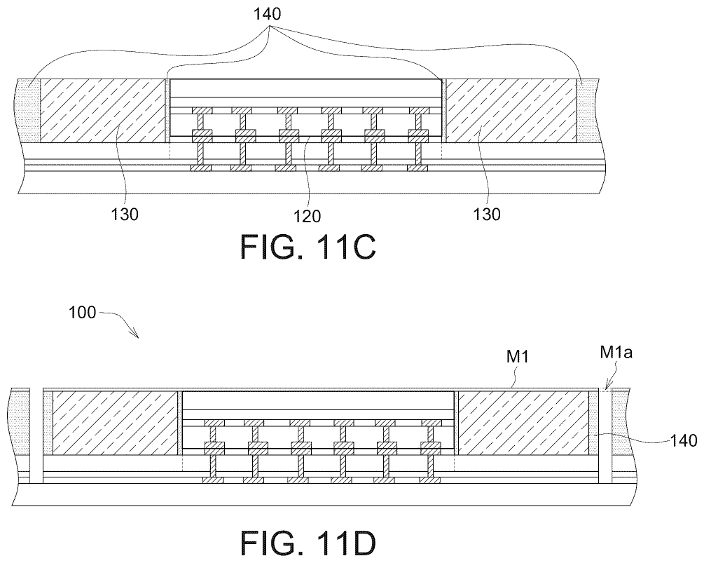

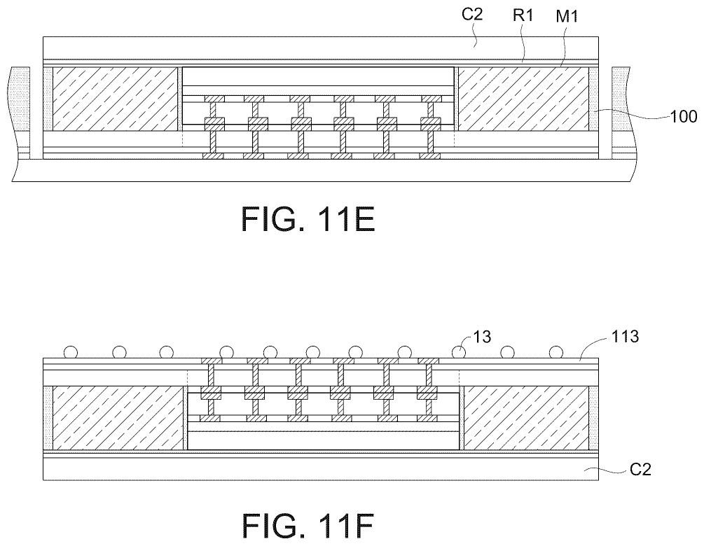

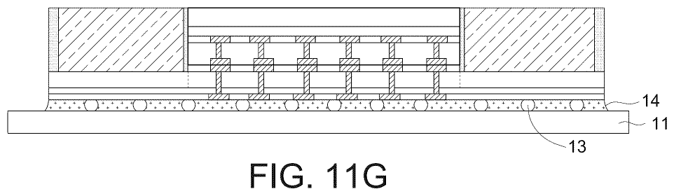

Referring to FIGS. 11A to 11G, FIGS. 11A to 11G illustrate schematic diagrams of manufacturing processes of the semiconductor chip 100 of FIG. 1.

As illustrated in FIG. 11A, the FEOL layer 112 is formed in the silicon base 111, the conductive vias 115 extending into the silicon base 111 are formed, and the BEOL layer 113 is formed on the FEOL layer 112 with the first conductive contacts 114 connected to the conductive vias 115. The structure is then flipped over and bonded to a temporary first carrier with a release layer C1. The first carrier C1 is, for example, a glass carrier containing a UV laser releaseable layer. Although not illustrated, a release film may be disposed between the first carrier C1 and the BEOL layer 113.

Then, as illustrated in FIG. 11B, the silicon base 111 may be planarized by, for example, CMP (chemical-mechanical polishing) to expose the conductive vias 115. Subsequently, a dielectric layer 117 is formed on the silicon base 111, and the second conductive contacts 116 electrically connected with the conductive vias 115 are formed in the dielectric layer 117 to form the substrate 110.

As illustrated in FIG. 11C, the memory component 120 is disposed on the silicon base 111 of the substrate 110 using copper hybrid bonding, wherein the memory component 120 is electrically connected to the substrate 110, and the heat dissipation components 130 is bonded to the silicon base 111 of the substrate 110 using direct bonding.

Then, a molding compound 140 is applied to fill the gaps between the heat dissipation components 130 and the memory component 120, and cover the lateral surface of the heat dissipation components 130.

As illustrated in FIG. 11D, a portion of the molding compound 140 is removed by, for example, etching through a mask M1 with a plurality of opens M1a. After etching, the semiconductor chip 100 is formed.

As illustrated in FIG. 11E, a second carrier C2 is disposed on the semiconductor chip 100 with a release film R1. The second carrier C2 is, for example, a glass carrier and the release layer is, for instance, an UV laser release-able layer

As illustrated in FIG. 11F, a plurality of the electrical contacts 13 are formed on the BEOL layer 113.

As illustrated in FIG. 11G, the structure in FIG. 11F is disposed on the first substrate 11 through the electrical contacts 13 following the release of the second carrier C2. Then, an underfill 14 encapsulating the electrical contacts 13 is formed between the first substrate 11 and the substrate 110.

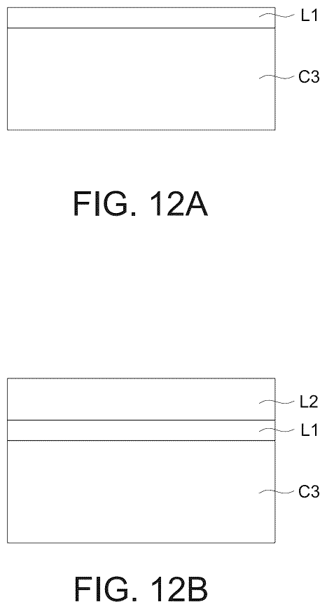

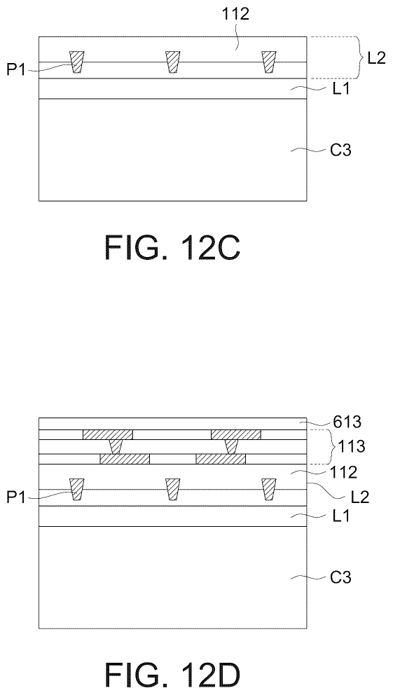

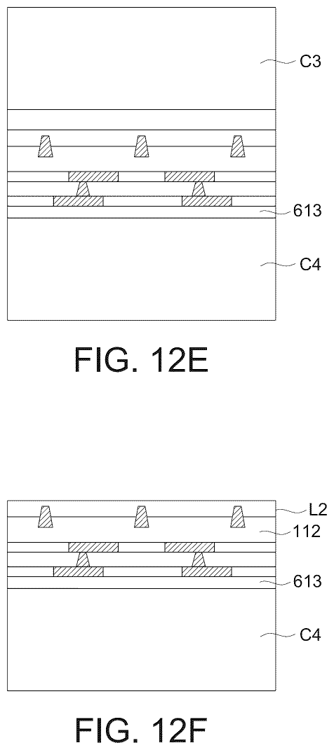

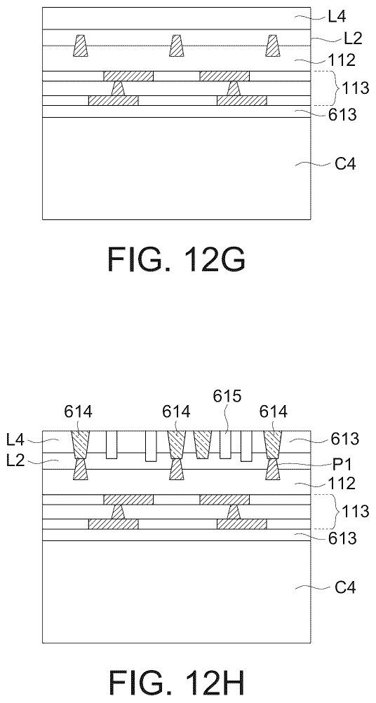

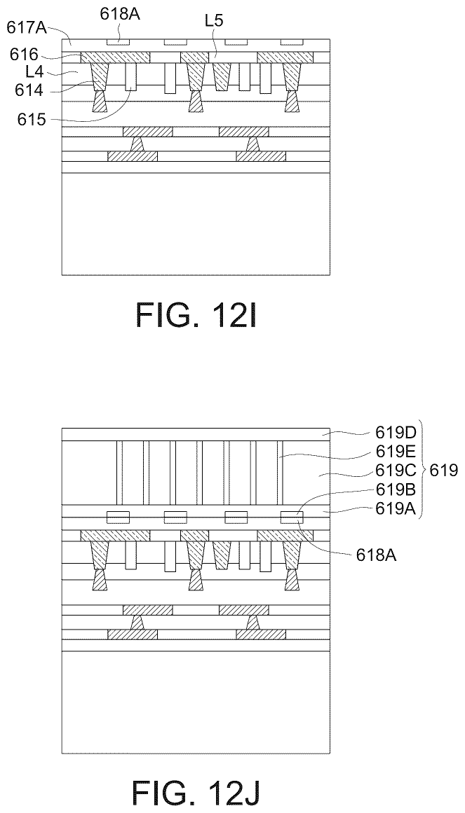

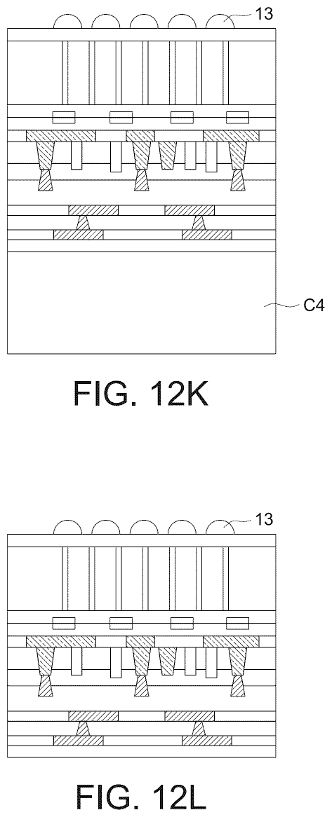

Referring to GIGS.. 12A to 12L, FIGS. 12A to 12L illustrate schematic diagrams of manufacturing processes of the substrate 610 in FIG. 6B.

As illustrated in FIG. 12A, a buffer stop layer L1 is formed on a first silicon substrate C3 by, for example, chemical vapor deposition, etc.

As illustrated in FIG. 12B, a silicon cap L2 is formed on the buffer stop layer L1 by, for example, epitaxial growth, etc. Then, the silicon cap L2 may be thinned by, for example, etching, back grinding, CMP, etc.

As illustrated in FIG. 12C, the FEOL layer 112 is formed on the silicon cap L2. The FEOL layer 112 includes a plurality of transistors (not illustrated), and the transistor includes, for example, a fin FET (field-effect transistor) structure, a nano-sheet structure, or a GAA structure. The power rails P1 are embedded in the FEOL layer 112 and silicon cap L2.

As illustrated in FIG. 12D, the BEOL layer 113 (which can include a local interconnect layer and an intermediate interconnect layer) is formed on the FEOL layer 112 by, for example, deposition, photolithography, etc. The RDL 613 is formed on the BEOL layer 113 by, for example, deposition, photolithography, etc.

As illustrated in FIG. 12E, the RDL 613 of the structure in FIG. 12D is disposed on a second silicon substrate C4.

As illustrated in FIG. 12F, the first silicon substrate C3 and the buffer stop layer L1 are removed to expose the silicon cap L2 by, for example, CMP, etching, etc.

As illustrated in FIG. 12G, a silicon dioxide layer L4 is formed on the silicon cap L2.

As illustrated in FIG. 12H, the first conductive vias 614 extending to the power rails P1 are formed in the silicon dioxide layer L4 and the silicon cap L2 by, for example, photolithography, etc., and the second conductive vias 615 are formed in the silicon oxide layer L4 and the silicon cap L2.

As illustrated in FIG. 12I, a dielectric layer L5 covering the first conductive vias 614 and the second conductive vias 615 is formed. Then, the power traces 616 connected with the first conductive vias 614 and the second conductive vias 615 are formed in the dielectric layer L5 by, for example, photolithography, deposition, etc. Then, the RDL 617A including the conductive pad 618A is formed over the dielectric layer L5 and the power trace 616.

As illustrated in FIG. 12J, the interposer 619 is disposed on the RDL 617A, wherein the conductive pads 619B of the interposer 619 are electrically connected with the conductive pad 618A.

As illustrated in FIG. 12K, the electrical contacts 13 are formed on the RDL 619D of the interposer 619.

As illustrated in FIG. 12L, the second silicon substrate C4 is removed.

The diamond layer in aforementioned embodiment may be formed by using the processes stated below.

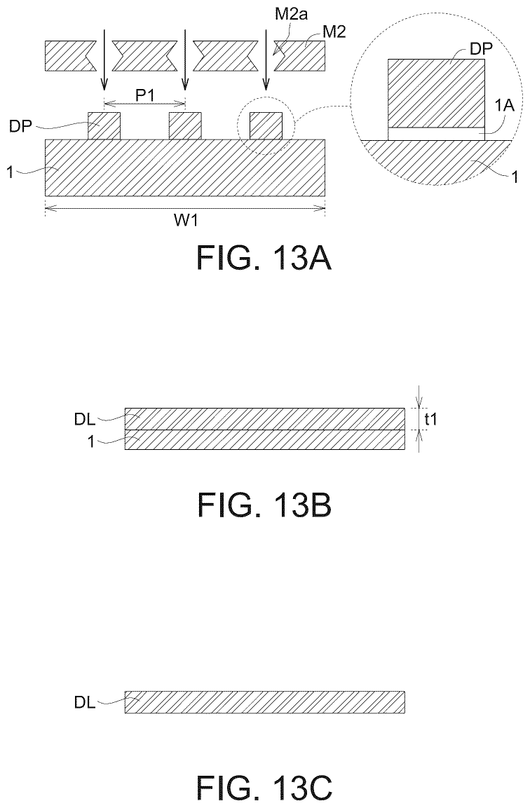

Referring to FIGS. 13A to 13C, FIGS. 13A to 13C illustrate manufacturing processes of a diamond layer DL according to an embodiment of the present disclosure.

As illustrated in FIG. 13A, a plurality of diamond particles DP is formed on a substrate 1 through a mask M2. The mask M2 has a plurality of holes M2a. The diamond particles DP are formed on the substrate 1 through the holes M2a. The substrate 1 is formed of a material including, for example, Mo (molybdenum). The substrate 1 has a length W1, for example, 1 (centimeter) cm, 2 cm, 3 cm, or 4 cm. The mask M2 is formed of a material including, for example, Mo. A pitch P1 between the adjacent two diamond particles DP is, for example, 20 micrometers (μm). In addition, the diamond particles DP may be formed (or adhered to) on the substrate 1 through a plurality of adhesion layers 1A.

As illustrated in FIG. 13B, the diamond layer DL is formed on the substrate 1 through the growth of the diamond particles DP by, for example, MPCVD. The diamond layer DL has a thickness t1, for example, 10 μm, 30 μm, 50 μm, 100 μm, etc.

As illustrated in FIG. 13C, the substrate 1 in FIG. 13B may be removed by, for example, thermo-mechanically removing technique, to form the diamond layer DL.

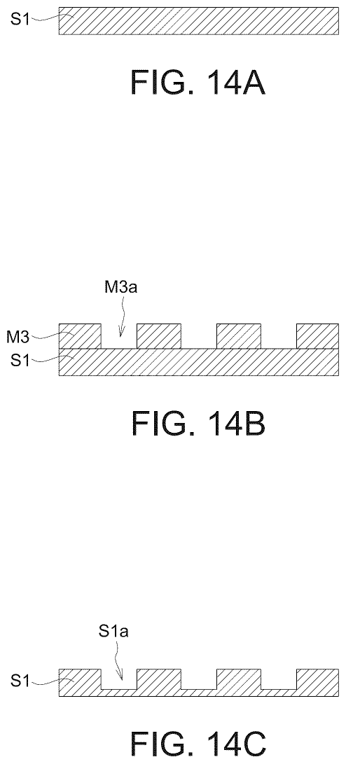

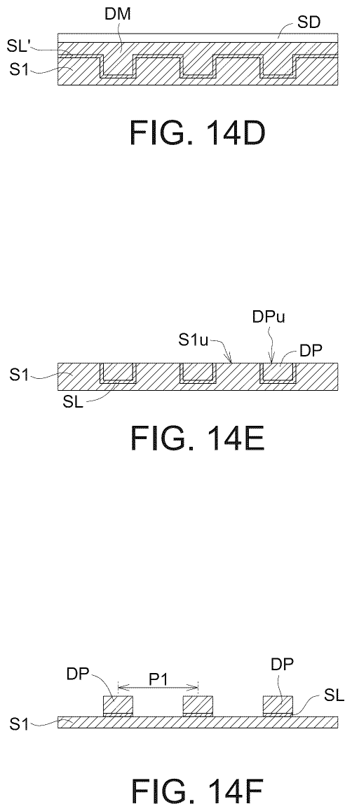

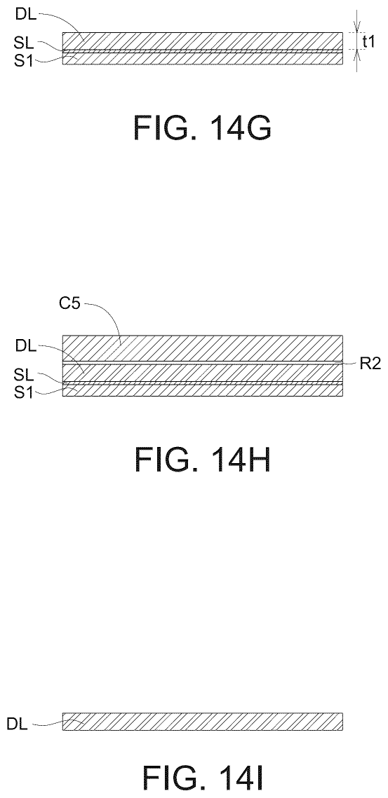

Referring to FIGS. 14A to 141, FIGS. 14A to 141 illustrate manufacturing processes of the diamond layer DL according to another embodiment of the present disclosure.

As illustrated in FIG. 14A, a silicon substrate S1 is provided.

As illustrated in FIG. 14B, a mask M3 having a plurality of holes M3a is formed on the silicon substrate S1. The mask M3 may be formed of a material including, for example, photosensitive polyimide (PSPI).

As illustrated in FIG. 14C, a plurality of recesses S1a is formed in the silicon substrate S1 to form a patterned substrate through the holes M3a of the mask M3 by, for example, dry etching (using SF₆). Then, the mask M3 may be removed.

In another embodiment, the patterned substrate in FIG. 14C may be formed by, for example, laser, wet etching, etc.

As illustrated in FIG. 14D, a seed layer material SL′ is formed on a surface of the silicon substrate S1 in FIG. 14C. The seed layer material SL′ is formed of a material including, for example, Ir on Si, Ir on SrTiO₃/Si or Ir on YSZ/Si. Then, a diamond material DM is formed on the silicon substrate S1 through the seed layer material SL′ by, for example, MPCVD. Then, a silicon dioxide SD is formed over the diamond material DM by, for example, CVD.

As illustrated in FIG. 14E, a portion of the seed layer material SL′, a portion of the diamond material DM, a portion of the silicon substrate S1 and the silicon dioxide SD are removed by, for example, CMP. After CMP, a remaining portion of the diamond material DM forms a plurality of the diamond particles DP. The diamond particle DP has an upper surface DPu, the silicon substrate S1 has an upper surface S1u, and the upper surface DPu and the upper surface S1u are flushed with each other. After CMP, a plurality of the diamond particles DP is located within the recesses S1a and over a plurality of the seed layers SL.

As illustrated in FIG. 14F, a portion of the silicon substrate S1 is removed through a mask (not illustrated), dry etching, etc. to expose a lateral surface of each diamond particle DP. The pitch P1 between the adjacent two diamond particles DP is, for example, 20 micrometers (μm). In addition, the diamond particles DP may be located over the silicon substrate S1 through a plurality of the seed layer SL.

As illustrated in FIG. 14G, the diamond layer DL is formed on the silicon substrate S1 through the growth of the diamond particles DP by, for example, MPCVD. The diamond layer DL has the thickness t1, for example, 10 μm, 30 μm, 50 μm, 100 μm, etc.

As illustrated in FIG. 14H, the structure of FIG. 14G is adhered to a temporary carrier C5 through a release layer R2.

As illustrated in FIG. 14I, the silicon substrate S1 in FIG. 14H is removed by, for example, wet etching, CMP, dry etching, etc. Then, the temporary carrier C5 may be released from the diamond layer DL through the release layer R2.

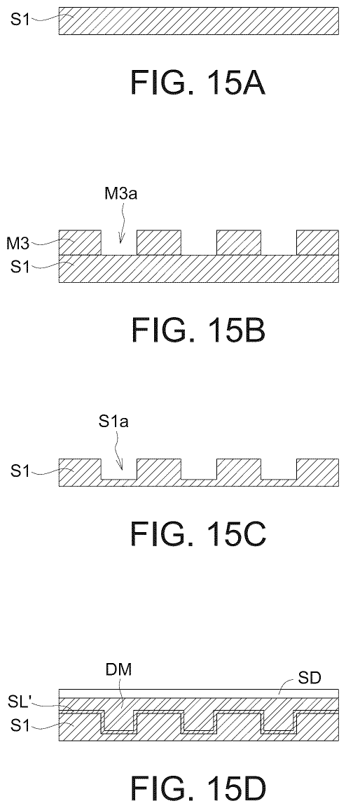

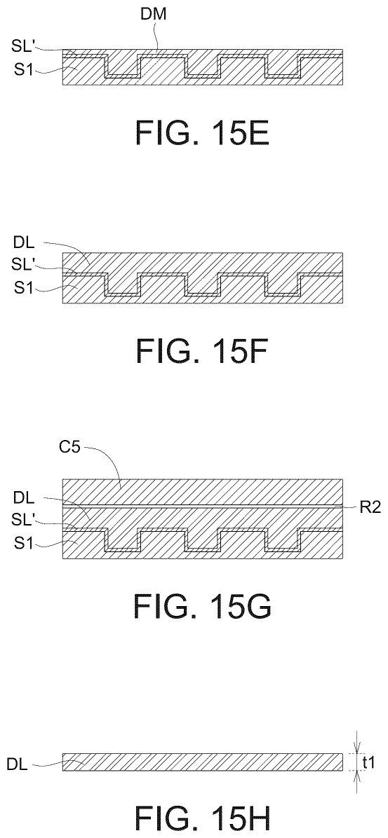

Referring to FIGS. 15A to 15H, FIGS. 15A to 15H illustrate manufacturing processes of the diamond layer DL according to another embodiment of the present disclosure.

As illustrated in FIG. 15A, the silicon substrate S1 is provided.

As illustrated in FIG. 15B, the mask M3 having a plurality of the holes M3a is formed on the silicon substrate S1. The mask M3 may be formed of a material including, for example, photosensitive polyimide.

As illustrated in FIG. 15C, a plurality of the recesses S1a is formed in the silicon substrate S1 through the holes M3a of the mask M3 by, for example, dry etching (using SF₆). Then, the mask M3 may be removed.

As illustrated in FIG. 15D, the seed layer material SL′ is formed the surface of the silicon substrate S1 in FIG. 15C. The seed layer material SL′ is formed of a material including, for example, Ir on Si, Ir on SrTiO₃/Si or Ir on YSZ/Si. Then, the diamond material DM is formed on the silicon substrate S1 through the seed layer material SL′ by, for example, MPCVD. Then, the silicon dioxide SD is formed over the diamond material DM by, for example, CVD.

As illustrated in FIG. 15E, a portion of the diamond material DM and the silicon dioxide SD are removed by, for example, CMP. After CMP, a remaining portion of the diamond material DM still covers the seed layer material SL′ and the silicon substrate S1.

As illustrated in FIG. 15F, the diamond layer DL is formed on the silicon substrate S1 through the growth of the diamond material DM by, for example, MPCVD.

As illustrated in FIG. 15G, the structure of FIG. 15F is adhered to the temporary carrier C5 through the release layer R2.

As illustrated in FIG. 15H, the silicon substrate S1 in FIG. 15G is removed by, for example, wet etching, CMP, dry etching, etc. to form the diamond layer DL. The diamond layer DL has the thickness t1 for example, 10 μm, 30 μm, 50 μm, 100 μm, etc. Then, the temporary carrier C5 may be released from the diamond layer DL through the release layer R2.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor device, comprising:
a substrate;
a memory component disposed on the substrate; and
a heat dissipation component disposed on the substrate;
wherein the heat dissipation component has a thermal conductivity greater than that of silicon.

2. The semiconductor device according claim 1, wherein the heat dissipation component is made of a material comprising diamond, aluminum nitride, boron nitride, boron arsenide, silicon carbide, metal or a combination thereof.

3. The semiconductor device according claim 1, wherein the memory component and the heat dissipation component are disposed side by side.

4. The semiconductor device according claim 1, further comprising:
a plurality of the heat dissipation components;
wherein the memory component is disposed between the heat dissipation components.

5. The semiconductor device according claim 1, further comprising:
a plurality of the memory components;
wherein the heat dissipation component is disposed between the memory components.

6. The semiconductor device according claim 1, further comprising:
a molding compound disposed between the memory component and the heat dissipation component.

7. The semiconductor device according claim 1, further comprising:
a plurality of the heat dissipation components; and
a molding compound disposed between the heat dissipation components.

8. The semiconductor device according claim 1, further comprising:
a plurality of the memory components; and
a molding compound disposed between the memory components.

9. The semiconductor device according claim 1, further comprising:
a heat spreader comprising a vapor chamber, covering the memory component and the heat dissipation component and having an upper surface;
a cooling component disposed on the upper surface of the heat spreader and having a fluid channel; and
a fan and/or a heat exchanger thermally coupled to the cooling component.

10. The semiconductor device according claim 9, further comprising:
a molding compound on a lateral surface of the heat dissipation component and having a lateral surface;
wherein the lateral surface of the molding compound and a lateral surface of the substrate are flushed with each other.

11. The semiconductor device according claim 1, wherein the substrate comprises:
a power rail layer;
a power supply layer connected with the power rail layer; and
an interposer disposed adjacent to and thermally coupled to the power supply layer, wherein the interposer is made of diamond, aluminum nitride, boron nitride, boron arsenide, silicon carbide, metal or a combination thereof.

12. The semiconductor device according claim 1, wherein the substrate comprises:
a back-end-of-line (BEOL) structure; and
a thermal Isolation structure disposed on and/or within the BEOL structure.

13. The semiconductor device according claim 1, wherein the substrate comprises:
a BEOL structure; and
a heat spreading structure disposed on and/or within the BEOL structure.

14. The semiconductor device according claim 1, wherein the substrate comprises:
a processor core;
a cache memory disposed adjacent to the processor core;
a thermal metamaterial structure disposed between the processor core and the cache memory and between the cache memory and the memory component to minimize thermal cross-talks, respectively, between the processor core and the cache memory and between the cache memory and the memory component.

15. The semiconductor device according claim 14, wherein the thermal metamaterial structure is a thermal-guiding ring comprising:
a first layer having a first thermal conductivity;
a second layer having a second thermal conductivity and surrounding the first layer; and
a third layer having a third thermal conductivity and surrounding the second layer;
wherein the second thermal conductivity is greater than the first thermal conductivity, and the first thermal conductivity is greater than the third thermal conductivity.

16. The semiconductor device according claim 15, wherein the first layer is formed of silicon, the second layer is formed of graphene, and the third layer is formed of silicon dioxide.

17. The semiconductor device according claim 1, where the semiconductor device is mounted on a HTC and LCTE substrate.
